(19) United States
(12) Patent Application Publication
(10) Pub. No.: US 2025/0380475 A1
(43) Pub. Date: Dec. 11, 2025

(54) SEMICONDUCTOR DEVICE WITH A FIRST ISOLATION TRENCH AND A SECOND ISOLATION TRENCH AND METHOD OF MANUFACTURING

(71) Applicant: Infineon Technologies AG, Neubiberg (DE)

(72) Inventors: Till Schlösser, München (DE); Ralf Rudolf, Dresden (DE)

(21) Appl. No.: 19/230,175

(22) Filed: Jun. 6, 2025

(30) Foreign Application Priority Data
Jun. 7, 2024 (DE) 102024205258.2

(51) Int. Cl. H10D 62/10; H01L 21/762; H10D 62/60; H10D 84/00; H10D 84/60; H10D 84/80

(52) U.S. Cl. CPC H10D 62/126; H01L 21/76229; H01L 21/76232; H10D 62/60; H10D 84/204; H10D 84/611; H10D 84/811

(57) ABSTRACT

A semiconductor device includes a buried semiconductor substrate layer interposed between a lower semiconductor substrate layer of a different conductivity type and an upper semiconductor substrate layer. A first isolation trench extends through the upper semiconductor substrate layer and the buried semiconductor substrate layer into the lower semiconductor substrate layer, includes a first insulating material formed at an inner sidewall of the first isolation trench, and is filled with a first electrically conductive material. A second isolation trench extends through the upper semiconductor substrate layer and the buried semiconductor substrate layer into the lower semiconductor substrate layer, includes a second insulating material formed at an inner sidewall and a bottom of the second isolation trench, and is either devoid of a second electrically conductive material or only a minor portion of the second isolation trench is filled with the second electrically conductive material.

### TECHNICAL FIELD

The present disclosure relates to a semiconductor device with a first isolation trench and a second isolation trench, and a method of manufacturing a semiconductor device.

### BACKGROUND

Integrated power technologies have evolved to where entire electronic systems are built into a single integrated circuit chip. The single chip combines analog, digital/logic and/or power functions to provide system functions. The single chip replaces multiple integrated circuit chips and enables manufacturers to build smaller systems. Applications include systems in the automotive, industrial, telecommunication, and data processing fields. The single chip can be manufactured via a bipolar, complementary metal oxide semiconductor (CMOS), double-diffused metal oxide semiconductor (DMOS) process, referred to as a BCD process. Within the single chip, an electrical isolation is required between parts of the chip operating at different voltage levels. For example, an electrical isolation is required between blocks operating at a high voltage and blocks operating at a lower voltage.

### SUMMARY

According to an example of a semiconductor device, the semiconductor device comprises a lower semiconductor substrate layer of a first conductivity type, an upper semiconductor substrate layer and a buried semiconductor substrate layer of a second conductivity type interposed between the lower semiconductor substrate layer and the upper semiconductor substrate layer. The semiconductor device further comprises a first isolation trench formed at a first main surface of the upper semiconductor substrate layer and extending through the upper semiconductor substrate layer and the buried semiconductor substrate layer into the lower semiconductor substrate layer. The first isolation trench comprises a first insulating material formed at an inner sidewall of the first isolation trench and the first isolation trench is filled with a first electrically conductive material. The semiconductor device further comprises a second isolation trench formed at the first main surface of the upper semiconductor substrate layer and extending through the upper semiconductor substrate layer and the buried semiconductor substrate layer into the lower semiconductor substrate layer. The second isolation trench comprises a second insulating material formed at an inner sidewall and a bottom of the second isolation trench and the second isolation trench is either devoid of a second electrically conductive material or only a minor portion (e.g., less than 50%) of the second isolation trench is filled with the second electrically conductive material.

According to an example of a method of manufacturing a semiconductor device, the method comprises forming a first isolation trench extending from a first main surface of an upper semiconductor substrate layer through the upper semiconductor substrate layer and through a buried semiconductor substrate layer into a lower semiconductor substrate layer. The method further comprises forming a second isolation trench extending from the first main surface of the upper semiconductor substrate layer through the upper semiconductor substrate layer and through the buried semiconductor substrate layer into the lower semiconductor substrate layer. The method further comprises forming a first insulating material which covers an inner sidewall of the first isolation trench and forming a second insulating material which covers an inner sidewall and a bottom of the second isolation trench. The method further comprises filling the first isolation trench with a first electrically conductive material and filling only a minor portion (e.g., less than 50%) of the second isolation trench with a second electrically conductive material or not filling of the second isolation trench with the second electrically conductive material.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements unless indicated otherwise. The elements of the drawings are not necessarily drawn to scale relative to each other. The features of the various illustrated examples can be combined unless they exclude each other.

FIGS. 1A-1B, FIGS. 2-3 and FIGS. 4A-4B illustrate partial cross-sectional views of exemplary semiconductor devices;

FIG. 5 and FIGS. 6A-6B illustrate partial top views of exemplary semiconductor devices; and

FIGS. 7A-7I illustrate a series of cross-sectional views of an exemplary method of manufacturing a semiconductor device.

### DETAILED DESCRIPTION

The making and using of several examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The terms “on” and “over” are not to be construed as meaning only “directly on” and “directly over”. Rather, if one element is positioned “on” or “over” another element (e. g., a layer is “on” or “over” another layer or “on” or “over” a substrate), a further component (e. g., a further layer) may be positioned between the two elements (e. g., a further layer may be positioned between a layer and a substrate if the layer is “on” or “over” said substrate).

Spatially relative terms, such as “beneath”, “below”, “lower”, “above”, “upper”, “under” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

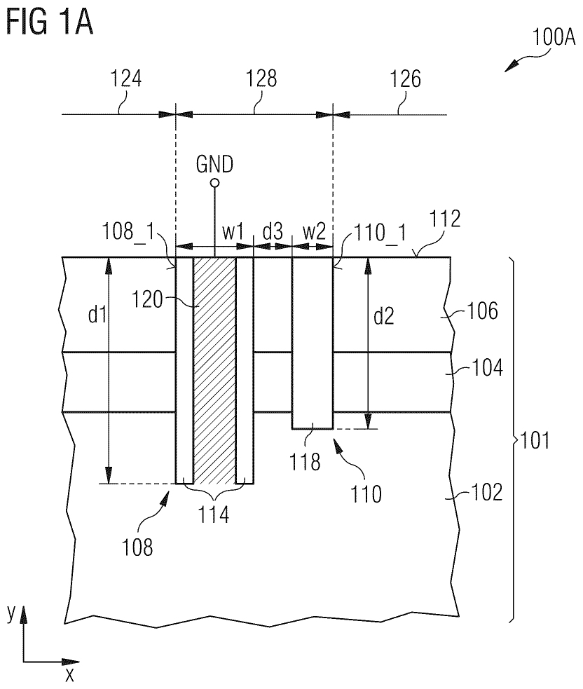

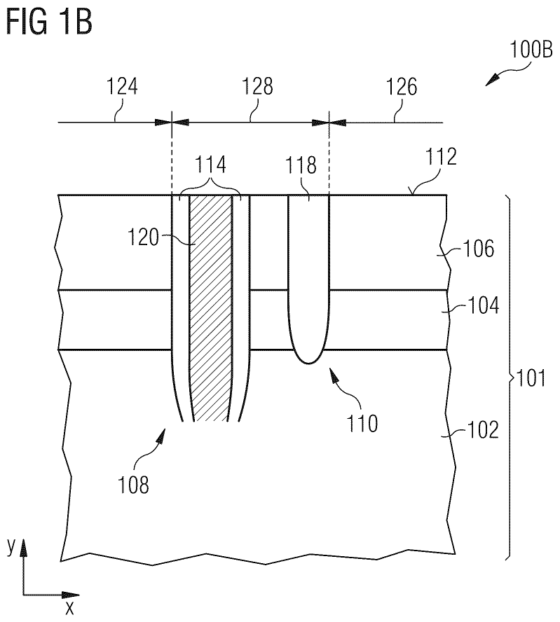

FIG. 1A illustrates a partial cross-sectional view of an exemplary semiconductor device 100A. The semiconductor device 100A includes a semiconductor substrate 101. The substrate 101 may include one or more of a variety of semiconductor materials that are used to form semiconductor devices. For example, the substrate 101 may include single element semiconductors (e. g. Si, Ge, etc.), silicon-on-insulator semiconductors, binary semiconductors (e. g. SiC, GaN, GaAs, SiGe, etc.), ternary semiconductors (e. g. AlGaN, InGaAs, InAlAs, etc.). The substrate 101 has a first main surface 112 and a second main surface (not illustrated) opposite the first main surface 112. The first main surface 112 may be referred to as a front surface and the second main surface may be referred to as a back surface. A first direction x is parallel to the first main surface 112 of the substrate 101. The first direction x may be referred to as a horizontal or a lateral direction x.

The substrate 101 includes a lower semiconductor substrate layer 102 of a first conductivity type and an upper semiconductor substrate layer 106. An upper surface 112 of the upper semiconductor substrate layer 106 coincidences with the first main surface 112 of the substrate 101. The upper surface 112 of the upper semiconductor substrate layer 106 may be referred to as a first main surface 112 of the upper semiconductor substrate layer 106. The substrate 101 further includes a buried semiconductor substrate layer 104 of a second conductivity type that is opposite to the first conductivity type. The buried semiconductor substrate layer 104 is interposed between the lower semiconductor substrate layer 102 and the upper semiconductor substrate layer 106 in a second direction y which is perpendicular to the first direction x. The second direction y may be referred to as a vertical direction y.

The buried semiconductor substrate layer 104 is a conductive layer that may be formed by implantation of dopants into the substrate 101, deposition of a doped semiconductor material, or epitaxial growth of semiconductor material, for example. The buried semiconductor substrate layer 104 may be referred to as a buried layer 104. In one example, the lower semiconductor substrate layer 102 is of p-type and has a lower dopant concentration than the buried layer 104 that is of n-type. The buried layer 104 may be positioned directly on the lower semiconductor substrate layer 102. Alternatively, one or more intermediate layers may be interposed between the buried layer 104 and the lower semiconductor substrate layer 102.

The upper semiconductor substrate layer 106 may be positioned directly on the buried layer 104. Alternatively, one or more intermediate layers may be interposed between the upper semiconductor substrate layer 106 and the buried layer 104. The upper semiconductor substrate layer 106 is a conductive layer that may be formed by implantation of dopants into the substrate 101, deposition of a doped semiconductor material, or epitaxial growth of semiconductor material, for example. The upper semiconductor substrate layer 106 may be of the first conductivity type or the second conductivity type. In one example, the upper semiconductor substrate layer 106 has the same conductivity type as the buried layer 104 and has a lower dopant concentration than the buried layer 104. The upper semiconductor substrate layer 106 includes well regions and/or doped regions that form part of functional devices that are at least partly formed within the upper semiconductor substrate layer 106. The functional device may be an active or a passive semiconductor device.

A first isolation trench 108 is provided at the first main surface 112 of the upper semiconductor substrate layer 106 and extends through the upper semiconductor substrate layer 106 and the buried semiconductor substrate layer 104 into the lower semiconductor substrate layer 102. That means, starting from the first main surface 112 of the upper semiconductor substrate layer 106, the first isolation trench 108 penetrates the upper semiconductor substrate layer 106 and the buried semiconductor substrate layer 104 and extends into the lower semiconductor substrate layer 102. A bottom of the first isolation trench 108 resides within the lower semiconductor substrate layer 102. That means, the bottom of the first isolation trench 108 does not reach a lower surface of the lower semiconductor substrate layer 102. The first isolation trench 108 may be referred to as a deep trench isolation.

Besides, a second isolation trench 110 is provided at the first main surface 112 of the upper semiconductor substrate layer 106 and extends through the upper semiconductor substrate layer 106 and the buried semiconductor substrate layer 104 into the lower semiconductor substrate layer 102. That means, starting from the first main surface 112 of the upper semiconductor substrate layer 106, the second isolation trench 110 penetrates the upper semiconductor substrate layer 106 and the buried semiconductor substrate layer 104 and extends into the lower semiconductor substrate layer 102. A bottom of the second isolation trench 110 resides within the lower semiconductor substrate layer 102. That means, the bottom of the second isolation trench 110 does not reach a lower surface of the lower semiconductor substrate layer 102. The second isolation trench 110 may be referred to as a deep trench isolation.

As illustrated in FIG. 1A, the first isolation trench 108 contains a first insulating material 114 that lines an inner sidewall of the first isolation trench 108. The first insulating material 114 may be referred to as a liner. The first insulating material 114 may include grown and/or deposited oxide, for example. Moreover, the first isolation trench 108 is filled with a first electrically conductive material 120. The first electrically conductive material 120 may include highly doped polysilicon, a metal-semiconductor compound, a metal, and/or a metal alloy. In one example, the first electrically conductive material 120 has the same conductivity type as the lower semiconductor substrate layer 102 and has a higher dopant concentration than the lower semiconductor substrate layer 102. The first electrically conductive material 120 is separated from the upper semiconductor substrate layer 106 and the buried layer 104 by the first insulating material 114. A bottom portion of the first isolation trench 108 is devoid of any insulating material 114 and therefore, the first electrically conductive material 120 is in contact with the lower semiconductor substrate layer 102 at the bottom portion of the first isolation trench 108.

In the example of FIG. 1A, the lower semiconductor substrate layer 102 is configured to be set to an electrical potential via the first electrically conductive material 120 and via an opening of the first insulating material 114 at the bottom of the first isolation trench 108. In one example, the lower semiconductor substrate layer 102 is configured to be set to a voltage supply potential and/or a ground potential. By biasing the lower semiconductor substrate layer 102 to a predefined voltage potential, e.g., to the ground potential, the formation of a parasitic device within the semiconductor device 100A may be suppressed or deteriorated. In the example of FIG. 1A, the first electrically conductive material 120 is configured to be set to the ground potential GND to bias the lower semiconductor substrate layer 102. The formation of a parasitic bipolar transistor having the lower semiconductor substrate layer 102 as a base is avoided. It is to be noted that FIG. 1A shows a schematic representation of the connection of the first electrically conductive material 120 to the ground potential GND. For ease of illustration, electrically conductive layers that are formed over the substrate 101 and that form part of this connection are not illustrated in FIG. 1A. While in the example of FIG. 1A the lower semiconductor substrate layer 102 is configured to be set to an electrical potential via the first electrically conductive material 120 and via an opening of the first insulating material 114 at the bottom of the first isolation trench 108, in other examples, the lower semiconductor substrate layer 102 is configured to be set to an electrical potential in a different way, e. g., by using a sinker.

As further illustrated in FIG. 1A, a second insulating material 118 is formed at an inner sidewall and a bottom of the second isolation trench 110. The second insulating material 118 may include grown and/or deposited oxide, for example. In the example of FIG. 1A, the second isolation trench 110 is devoid of electrically conductive material. That means, the second isolation trench 110 does not contain any electrically conductive material. Instead, the second isolation trench 110 is completely filled with the second insulating material 118. The second insulating material 118 extends from the first main surface 112 of the substrate 101 to the bottom of the second isolation trench 110. There is no electrically conductive material contained in the second isolation trench 110 that may be electrically floating, i.e., that may not be directly connected to an electrical potential. As a consequence, no charging of electrically conductive material that is included within the second isolation trench 110 occurs during operational lifetime of the semiconductor device 100A. Such a charging may be induced by leakage currents that may occur during operation of the semiconductor device 100A. The avoidance of such a charging may prevent a drift of a breakdown voltage of the semiconductor device 100A.

As illustrated in the example of FIG. 1A, the first isolation trench 108 has a first width w1, the second isolation trench 110 has a second width w2 and the first width w1 is larger than the second width w2. The first width w1 and the second width w2 may be measured at a position at the first main surface 112 of the substrate 101. Besides, the first isolation trench 108 has a first depth d1, the second isolation trench 110 has a second depth d2 and the first depth d1 is larger than the second depth d2. The first depth d1 and the second depth d2 may be measured starting from a position at the first main surface 112 of the substrate 101 to the bottom of the first isolation trench 108 and the second isolation trench 110, respectively. In one example, the first isolation trench 108 and the second isolation trench 110 are manufactured in a same processing step. Similarly, the first insulating material 114 is formed in the first isolation trench 108 in a same manufacturing step as the second insulating material 118 is formed in the second isolation trench 110. The second width w2 may be determined by technological limitations, e.g., of a lithography process. The second width w2 may be dimensioned in a way that the second isolation trench 110 is completely filled with the second insulating material 118. In contrast to that, the first width w1 is defined in a way that the first insulating material 114 covers only inner sidewalls of the first isolation trench 108. As a consequence, in a subsequent manufacturing step, the first electrically conductive material 120 is only formed in the first isolation trench 108 but not in the second isolation trench 110.

As further illustrated in FIG. 1A, the first isolation trench 108 and the second isolation trench 110 are arranged in an isolation region 128 of the semiconductor device 100A. The first isolation trench 108 and the second isolation trench 110 may be referred to as a dual trench isolation structure or a double trench isolation structure. It is to be noted that in some examples (some of which will be described in more detail below), the isolation region 128 may include further isolation trenches that are similar or same as the first isolation trench 108 and/or the second isolation trench 110. The semiconductor device 100A further includes a first functional device region 124 that is located at a side 108_1 of the first isolation trench 108 that faces away from the second isolation trench 110. Moreover, the semiconductor device 100A includes a second functional device region 126 that is located at a side 110_1 of the second isolation trench 110 that faces away from the first isolation trench 108. The first functional device region 124 is distinct from the second functional device region 126. The first functional device region 124, the second functional device region 126 and the isolation region 128 are contained in a same semiconductor die. The isolation region 128 is arranged between the first functional device region 124 and the second functional device region 126. The first functional device region 124 includes at least one active or passive semiconductor device and the second functional device region 126 includes at least one active or passive semiconductor device. In one example, the passive semiconductor device may be at least one of an inductor, a capacitor, or a resistor. In one example, the active semiconductor device may be at least one of a transistor, or a diode, e. g., a power transistor, or a power diode. The at least one active or passive semiconductor device of the first functional device region 124 and the second functional device region 126 may be implemented using a mixed technology. Such a mixed technology may be used, for example, to form analog circuit blocks using bipolar devices, to form digital circuit blocks using CMOS (Complementary Metal Oxide Semiconductor) devices, and to form low-, medium- or high-voltage or power blocks using DMOS (Double-Diffused Metal Oxide Semiconductor) devices. Such a mixed technology is known, for example, as BCD (Bipolar CMOS DMOS) technology or SPT (Smart Power Technology) or BiCMOS technology when combining Bipolar and CMOS technology.

The first functional device region 124 includes well regions and/or doped regions in the upper semiconductor substrate layer 106 that form parts of the at least one active or passive semiconductor device of the first functional device region 124. Similarly, the second functional device region 126 includes well regions and/or doped regions in the upper semiconductor substrate layer 106 that form parts of the at least one active or passive semiconductor device of the second functional device region 126. In one example, the at least one active or passive semiconductor device of the first functional device region 124 is configured to operate at a different voltage level than the at least one active or passive semiconductor device of the second functional device region 126. In one example, the at least one active or passive semiconductor device of the first functional device region 124 has a different breakdown voltage than the at least one active or passive semiconductor device of the second functional device region 126. Besides, the buried semiconductor substrate layer 104 in the first functional device region 124 is configured to be biased to a different voltage level than the buried semiconductor substrate layer 104 in the second functional device region 126. In one example, the buried semiconductor substrate layer 104 in the first functional device region 124 and the buried semiconductor substrate layer 104 in the second functional device region 126, respectively, are configured to biased by connecting them to a voltage potential via sinkers (not illustrated). The sinkers extend from the first main surface 112 of the substrate 101 to the buried semiconductor substrate layer 104 in the first functional device region 124 and to the buried semiconductor substrate layer 104 in the second functional device region 126, respectively.

The first isolation trench 108 and the second isolation trench 110 electrically isolate the first functional device region 124 from the second functional device region 126. More specific, the first isolation trench 108 and the second isolation trench 110 separate the upper semiconductor substrate layer 106 in the second functional device region 126 from the upper semiconductor substrate layer 106 in the first functional device region 124. Similarly, the first isolation trench 108 and the second isolation trench 110 separate the buried semiconductor substrate layer 104 in the second functional device region 126 from the buried semiconductor substrate layer 104 in the first functional device region 124.

In one example, the active or passive semiconductor device of the second functional device region 126 is configured to operate at a higher voltage level than the active or passive semiconductor device of the first functional device region 124. That means, the active or passive semiconductor device included in the second functional device region 126 has a higher operating voltage or a higher operating range than the active or passive semiconductor device included in first functional device region 124. During operation of the semiconductor device 100A, the upper semiconductor substrate layer 106 in the second functional device region 126 is at a higher voltage level than the upper semiconductor substrate layer 106 in the first functional device region 124. Similarly, the buried semiconductor substrate layer 104 in the second functional device region 126 is biased to a higher voltage level than the buried semiconductor substrate layer 104 in the first functional device region 124. In one example, the active or passive semiconductor device of the second functional device region 126 is rated to operate at a voltage of 60 V, 80 V, 90 V, 120 V or even higher. In one example, the active or passive semiconductor device of the first functional device region 124 is rated to operate at a voltage of 1.5 V, 3.3 V, 5 V, 20 V or 40 V. The first isolation trench 108 and the second isolation trench 110 are configured to act as a kind of capacitive voltage divider that divides the higher operating voltage or higher voltage level of the second functional device region 126 down to a lower operating voltage or lower voltage level of the first functional device region 124. In one example, the first isolation trench 108 and the second isolation trench 110 are configured to act as a kind of capacitive voltage divider that divides the higher voltage level of the buried semiconductor substrate layer 104 in the second functional device region 126 down to a lower voltage level of the buried semiconductor substrate layer 104 in the first functional device region 124.

As illustrated in the example of FIG. 1A, a region between the first isolation trench 108 and the second isolation trench 110 is devoid of functional devices. That means, the upper semiconductor substrate layer 106 in the isolation region 128 may not include any parts of active or passive semiconductor device. In one example, the upper semiconductor substrate layer 106 as well as the buried semiconductor substrate layer 104 in the isolation region 128 are configured to be electrically floating. A distance d3 between the first isolation trench 108 and the second isolation trench 110 is measured at a position at the first main surface 112 of the substrate 101 along the first direction x. In one example, the distance d3 is less that the first width w1. The distance d3 may correspond to a minimum distance that is determined by technological limitations in order to allow for an area efficient implementation of the semiconductor device 100A.

FIG. 1B illustrates a further partial cross-sectional view of an exemplary semiconductor device 100B. The semiconductor device 100B of FIG. 1B is similar to the semiconductor device 100A as illustrated and described in connection with FIG. 1A. Differently, the first isolation trench 108 and the second isolation trench 110 of the semiconductor device 100B of FIG. 1B have tapered sidewalls. The sidewalls are tapered with respect to the vertical direction y. Such a tapered sidewall may facilitate a filling of the first isolation trench 108 and the second isolation trench 110 with conductive and/or insulating material. In the example of FIG. 1B, at least one sidewall of the first isolation trench 108 as well as at least one sidewall of the second isolation trench 110 are tapered. In other examples, at least one sidewall of just one of the first isolation trench 108 or the second isolation trench 110 is tapered.

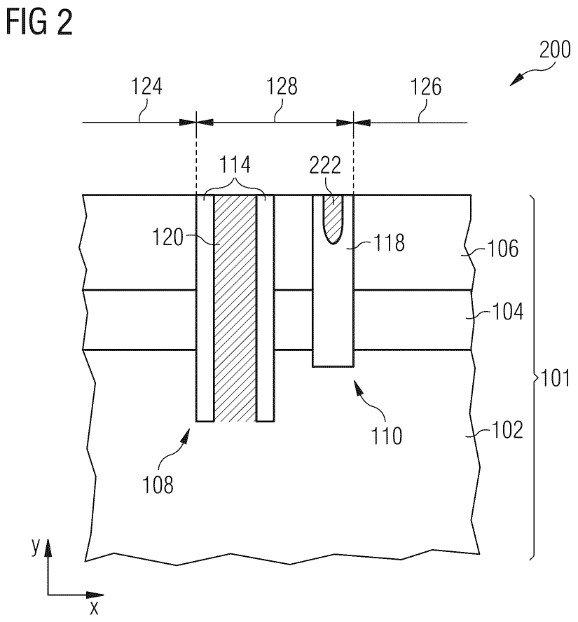

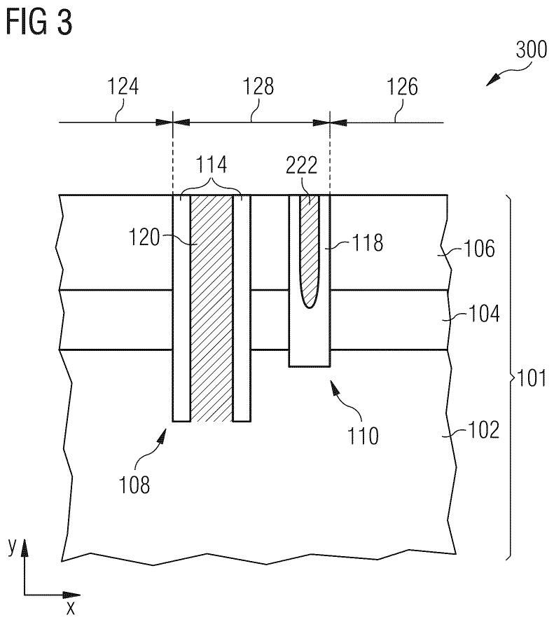

FIG. 2 and FIG. 3 illustrate further partial cross-sectional views of exemplary semiconductor devices 200, 300. The semiconductor devices 200, 300 of FIG. 2 and FIG. 3 are similar to the semiconductor device 100A as illustrated and described in connection with FIG. 1A. Differently, in the semiconductor devices 200, 300 of FIG. 2 and FIG. 3, a minor portion (e.g., less than 50%) of the second isolation trench 110 is filled with a second electrically conductive material 222. The second electrically conductive material 222 may include highly doped polysilicon, a metal-semiconductor compound, a metal, and/or a metal alloy. The second electrically conductive material 222 is separated from the substrate 101 by the second insulating material 118. In one example, the second electrically conductive material 222 is configured to be electrically floating. That means, the second electrically conductive material 222 is not electrically connected to a controllable contact and there is no connection line that directly connects the second electrically conductive material 222 to an electrical potential. This allows for area efficient implementations of the semiconductor devices 200, 300.

In one example, less than 50% of the second isolation trench 110 is filled with the second electrically conductive material 222. In other examples, less than 40%, less than 30%, less than 20%, less than 10%, or less than 5% of the second isolation trench 110 is filled with the second electrically conductive material 222. In one example, at least 2% of the second isolation trench 110 is filled with the second electrically conductive material 222. In other examples, at least 5%, at least 10%, at least 15%, or at least 20% of the second isolation trench 110 is filled with the second electrically conductive material 222. The second electrically conductive material 222 does not reach the bottom of the second isolation trench 110. Filling only a minor portion (e.g., less than 50%) of the second isolation trench 110 with the second electrically conductive material 222 prevents a negative influence on the function of the semiconductor devices 200, 300. For example, a charging of the second electrically conductive material 222 that may be induced by leakage currents may be negligible.

In the example of FIG. 2, the second electrically conductive material 222 extends from the first main surface 112 of the substrate 101 into the upper semiconductor substrate layer 106. A bottom portion of the second electrically conductive material 222 is located within the upper semiconductor substrate layer 106. That means, the second electrically conductive material 222 does not penetrate the upper semiconductor substrate layer 106 and therefore, does not extend to or into the buried semiconductor substrate layer 104. That means, the second electrically conductive material 222 extends from the first main surface 112 into the vertical direction y and the bottom portion of the second electrically conductive material 222 does not reach a level that is defined by a lower surface of the upper semiconductor substrate layer 106.

In the example of FIG. 3, the second electrically conductive material 222 extends from the first main surface 112 of the substrate 101 through the upper semiconductor substrate layer 106 into the buried semiconductor substrate layer 104. A bottom portion of the second electrically conductive material 222 is located within the buried semiconductor substrate layer 104. That means, the second electrically conductive material 222 penetrates the upper semiconductor substrate layer 106 but does not penetrate the buried semiconductor substrate layer 104 and therefore, does not extend to or into the lower semiconductor substrate layer 102. That means, the second electrically conductive material 222 extends from the first main surface 112 into the vertical direction y through the level that is defined by the lower surface of the upper semiconductor substrate layer 106. The bottom portion of the second electrically conductive material 222 does not reach a level that is defined by a lower surface of the buried semiconductor substrate layer 104.

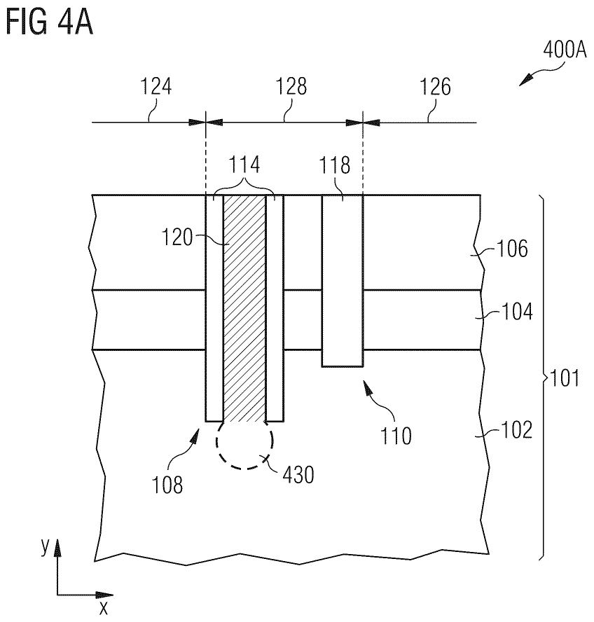

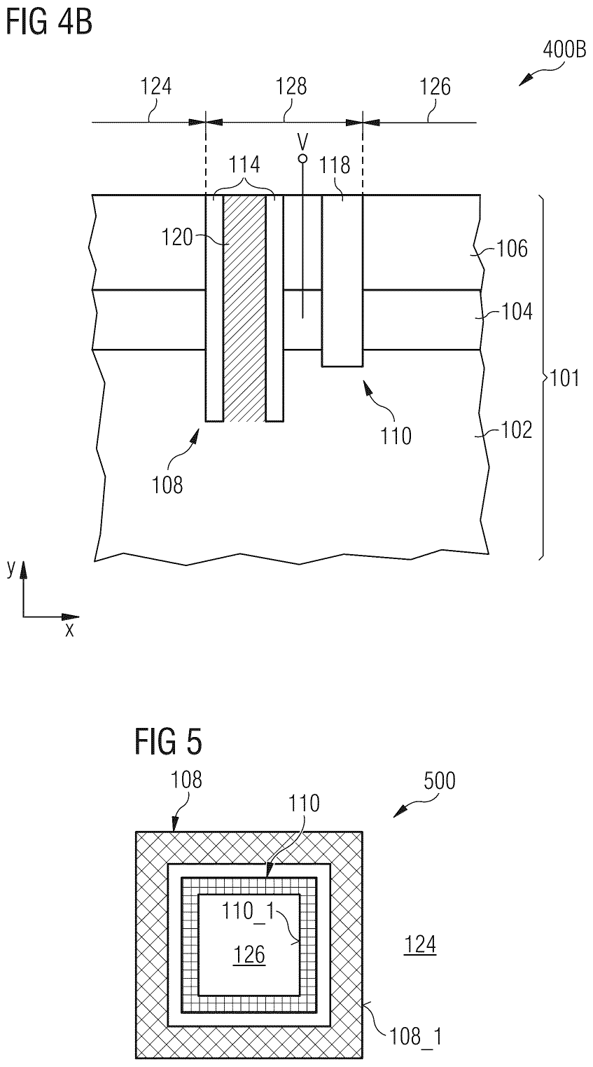

FIG. 4A illustrates a further partial cross-sectional view of an exemplary semiconductor device 400A. The semiconductor device 400A of FIG. 4A is similar to the semiconductor device 100A as illustrated and described in connection with FIG. 1A. Differently, the lower semiconductor substrate layer 102 of the semiconductor device 400A of FIG. 4A includes a region 430 that has a locally increased dopant concentration at the bottom of the first isolation trench 108. That means the region 430 has the same conductivity type as the lower semiconductor substrate layer 102 and has a higher dopant concentration than the lower semiconductor substrate layer 102. The region 430 allows for an improved electrical contact of the first electrically conductive material 120 to the lower semiconductor substrate layer 102.

FIG. 4B illustrates a further partial cross-sectional view of an exemplary semiconductor device 400B. The semiconductor device 400B of FIG. 4B is similar to the semiconductor device 100A as illustrated and described in connection with FIG. 1A. Differently, the buried semiconductor substrate layer 104 in the isolation region 128 of the semiconductor device 400B of FIG. 4B is configured to be set to a defined potential V. It is to be noted that FIG. 4B shows a schematic representation of the connection of the buried semiconductor substrate layer 104 in the isolation region 128 to the defined potential V. The defined potential V may be a positive voltage level. In one example, the defined potential V may be a voltage level that is between the operating voltage of the second functional device region 126 and the operating voltage of the first functional device region 124. In one example, the defined potential V may be a voltage level that is between the operating voltage of the second functional device region 126 and ground potential. The specified ranges include the boundary values. By setting the buried semiconductor substrate layer 104 in the isolation region 128 to a defined potential, a discharge of the buried semiconductor substrate layer 104 in the isolation region 128 is avoided and a stable operation of the semiconductor device 400B during operational lifetime of the semiconductor device 400B can be achieved.

It is to be noted that features of examples as illustrated in connection with FIGS. 1A-1B, FIGS. 2-3 and FIGS. 4A-4B may be combined. For example, first isolation trenches and second isolations trenches of FIGS. 2-3 and FIGS. 4A-4B may have tapered sidewalls. In another example, a region with locally increased dopant concentration may be provided at the bottom of the first isolation trenches of FIGS. 1A-1B, FIGS. 2-3 and FIG. 4B. In another example, the buried semiconductor substrate layer 104 in the isolation region 128 of FIGS. 1B, FIGS. 2-3 and FIG. 4A may be configured to be connected to a defined potential.

FIG. 5 illustrates a partial top view of an exemplary semiconductor device 500. The semiconductor device 500 may include semiconductor devices 100A and 100B, semiconductor devices 200 and 300, semiconductor devices 400A and 400B as illustrated and described in connection with FIGS. 1A-1B, 2-3, 4A-4B above, respectively. The semiconductor device 500 includes the second functional device region 126 that is surrounded by the second isolation trench 110. The second isolation trench 110 laterally surrounds the second functional device region 126. The semiconductor device 500 further includes the first isolation trench 108 that surrounds the second isolation trench 110. The first isolation trench 108 laterally surrounds the second isolation trench 110. That means, the second functional device region 126 is located at the side 110_1 of the second isolation trench 110 that faces away from the first isolation trench 108. The semiconductor device 500 further includes the first functional device region 124 that is located at the side 108_1 of the first isolation trench 108 that faces away from the second isolation trench 110. A region between the first isolation trench 108 and the second isolation trench 110 does not include any functional device. While in the example of FIG. 5 the second functional device region 126 is completely surrounded by the second isolation trench 110 and the second isolation trench 110 is completely surrounded by the first isolation trench 108, in other examples, the first isolation trench 108 and/or the second isolation trench 110 is interrupted and/or segmented. In one example, the second functional device region 126 is surrounded by the second isolation trench 110 at least partly. Similarly, the second isolation trench 110 is surrounded by the first isolation trench 108 at least partly. The first isolation trench 108 and the second isolation trench 110 may have a same or different shape. In a top view, the first isolation trench 108 and the second isolation trench 110 may be ring-, round-, oval-, square-, rectangular-, trapezoidal-, or hexagonal-shaped, or may have other shapes. While in the example of FIG. 5 the first isolation trench 108 runs in parallel with the second isolation trench 110, in other examples, the first isolation trench 108 and the second isolation trench 110 do not run parallel to each other.

In one example, an active or passive semiconductor device of the second functional device region 126 is configured to operate at a higher voltage level than an active or passive semiconductor device of the first functional device region 124. In other examples, this may be vice versa. In one example, one or more further isolation trenches may be provided between the first functional device region 124 and the second functional device region 126. The one or more further isolation trenches may be similar or same as the first isolation trench 108 and/or the second isolation trench 110. The one or more further isolation trenches may provide for an improved electrical isolation of a functional device located in the first functional device region 124 from a functional device located in the second functional device region 126. There may be no functional elements in an area between the one or more further isolation trenches and the first isolation trench 108 and/or the second isolation trench 110.

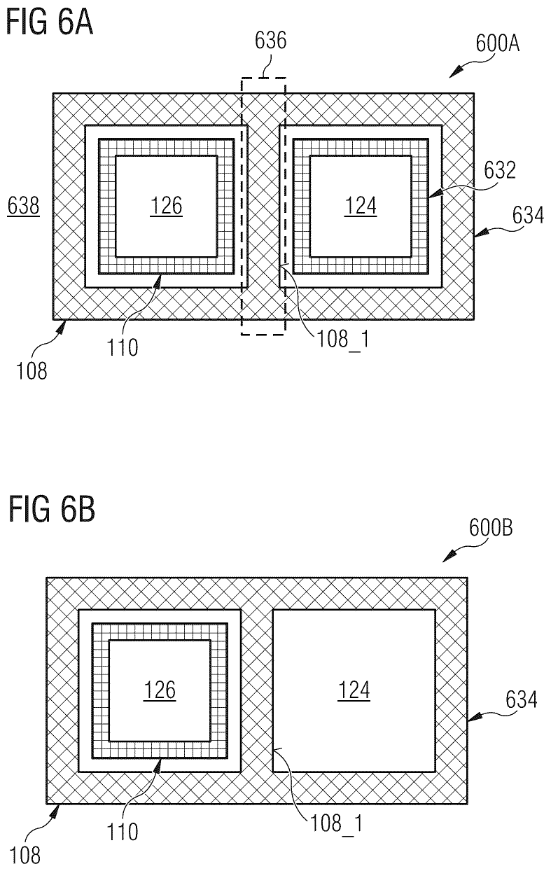

FIG. 6A illustrates a partial top view of an exemplary semiconductor device 600A. Similar to the semiconductor device 500 as illustrated and described in connection with FIG. 5, the semiconductor device 600A includes the second functional device region 126 that is surrounded by the second isolation trench 110. The semiconductor device 600A further includes the first isolation trench 108 that surrounds the second isolation trench 110. The semiconductor device 600A further includes the first functional device region 124 that is located at the side 108_1 of the first isolation trench 108 that faces away from the second isolation trench 110. Different to the semiconductor device 500 of FIG. 5, the semiconductor device 600A of FIG. 6A includes a third isolation trench 632 that surrounds the first functional device region 124. The third isolation trench 632 may be similar or same as the second isolation trench 110. Besides, the third isolation trench 632 is surrounded at least partly by a fourth isolation trench 634. The fourth isolation trench 634 may be similar or same as the first isolation trench 108.

As illustrated in the example of FIG. 6A, the fourth isolation trench 634 is connected to the first isolation trench 108. That means, the first isolation trench 108 and the fourth isolation trench 634 form a contiguous structure. The fourth isolation trench 634 may be referred to as a branch of the first isolation trench 108. In one example (not illustrated), there may be further isolation trenches that branch off from the first isolation trench 108 and/or the fourth isolation trench 634. Moreover, there may be further isolation trenches that branch off from the second isolation trench 110 and/or the third isolation trench 632. In the example of FIG. 6A, in a region 636 where the first functional device region 124 faces the second functional device region 126, the first isolation trench 108 may be shared between the first functional device region 124 and the second functional device region 126. In this example, as illustrated in FIG. 6A, there is no fourth isolation trench 634 in the region 636. The first isolation trench 108, the second isolation trench 110 and the third isolation trench 632 may be referred to as a triple trench isolation structure. In other examples (not illustrated), the fourth isolation trench 634 may completely surround the third isolation trench 632. In this example, both the fourth isolation trench 634 and the first isolation trench 108 are located in the region 636. The first isolation trench 108, the second isolation trench 110, the third isolation trench 632 and the fourth isolation trench 634 may be referred to as a quadruple trench isolation structure. In one example, devices of the first functional device region 124 are rated to operate at a first high voltage and devices of the second functional device region 126 are rated to operate at a second high voltage that is different from the first high voltage.

As illustrated in the example of FIG. 6A, the semiconductor device 600A further includes a third functional device region 638. The third functional device region 638 is distinct from the first functional device region 124 and the second functional device region 126. The third functional device region 638 includes at least one active or passive semiconductor device similar to the first functional device region 124 and the second functional device region 126. Devices of the third functional device region 638 may be rated to operate at a lower voltage compared to the devices of the first functional device region 124 and the second functional device region 126. In one example (not illustrated), the semiconductor device 600A may include further functional device regions. Generally, the isolation trenches electrically isolate the functional device regions from each other. More specific, the isolation trenches electrically isolate the upper semiconductor substrate layers 106 of the various functional device regions from each other. Besides, the isolation trenches electrically isolate the buried semiconductor substrate layers 104 of the various functional device regions from each other. An area between the isolation trenches may be devoid of any functional devices.

FIG. 6B illustrates a partial top view of an exemplary semiconductor device 600B. Similar to the semiconductor device 600A as illustrated and described in connection with FIG. 6A, the semiconductor device 600B includes the second functional device region 126 that is surrounded by the second isolation trench 110. The semiconductor device 600B further includes the first isolation trench 108 that surrounds the second isolation trench 110. The semiconductor device 600B further includes the first functional device region 124 that is located at the side 108_1 of the first isolation trench 108 that faces away from the second isolation trench 110. The first functional device region 124 is at least partly surrounded by the fourth isolation trench 634. Different to the semiconductor device 600A of FIG. 6A, the first functional device region 124 of the semiconductor device 600B of FIG. 6B is not surrounded by any third isolation trench that is similar or same as the second isolation trench 110. The first functional device region 124 is at least partly surrounded by a single isolation trench. That means, the first functional device region 124 is bounded by a single isolation trench and the first functional device region 124 is laterally surrounded by a single isolation trench. This single isolation trench includes the fourth isolation trench 634 and parts of the first isolation trench 108 that merge into one another. This single isolation trench has a larger width and a larger depth than the second isolation trench 110. In one example, devices of the second functional device region 126 are configured to operate at higher voltage than devices of the first functional device region 124. The semiconductor device 600B may include further functional device regions that are similar or same as the third functional device region 638 of FIG. 6A.

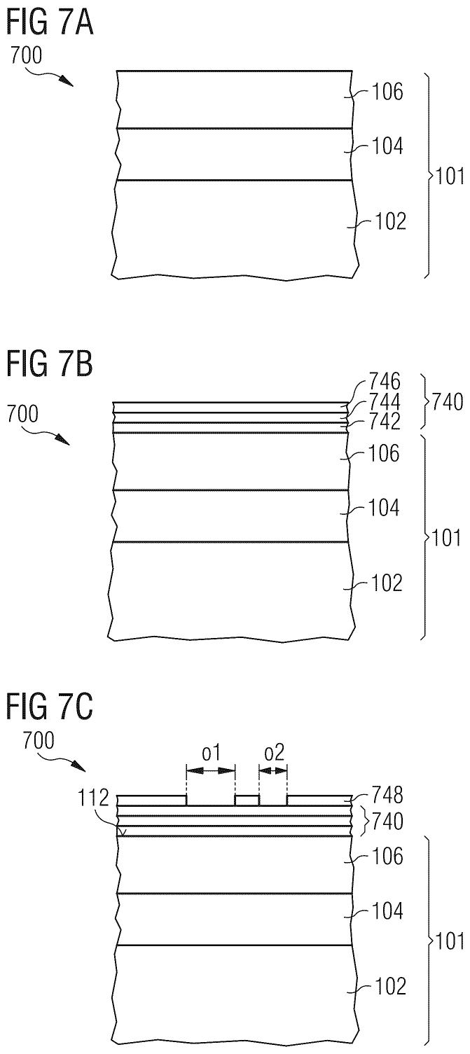

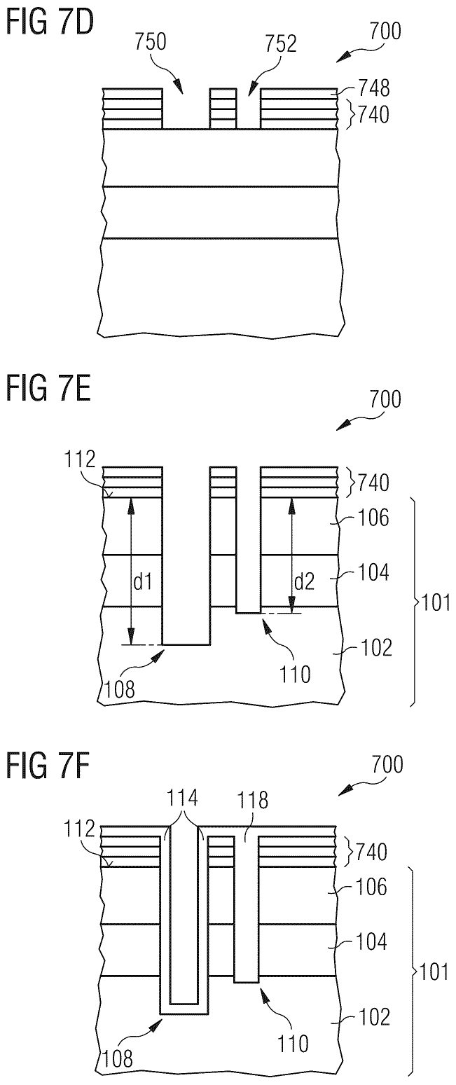

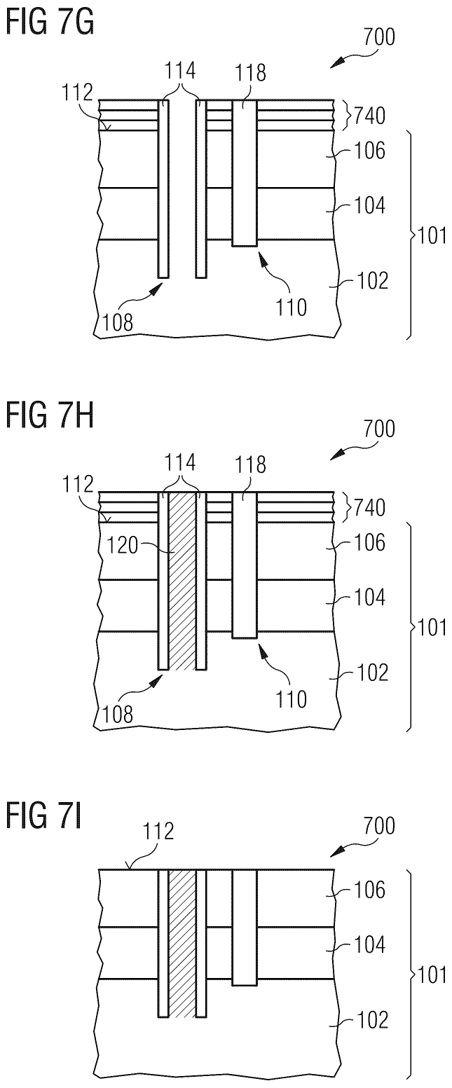

FIGS. 7A-7I illustrate a series of cross-sectional views of an exemplary method of manufacturing a semiconductor device 700. The method as will be described in connection with FIGS. 7A-7I may be used to manufacture a semiconductor device similar to one of the semiconductor devices 100A and 100B, semiconductor devices 200 and 300, semiconductor devices 400A and 400B, semiconductor devices 500, and semiconductor devices 600A and 600B as illustrated and described in connection with FIGS. 1A-1B, 2-3, 4A-4B, 5, and 6A-6B, respectively.

As shown in FIG. 7A, a semiconductor substrate 101 is provided that includes a buried semiconductor substrate layer 104 that is formed over a lower semiconductor substrate layer 102. The lower semiconductor substrate layer 102 has a first conductivity type and the buried semiconductor substrate layer 104 has a second conductivity type that is opposite to the first conductivity type. The lower semiconductor substrate layer 102 may be a bulk substrate, at least part of a silicon on insulator (SOI) substrate, or an epitaxial layer. The buried semiconductor substrate layer 104 may be formed by implantation of at least one dopant, e.g., arsenic (As) and/or phosphor (P) into the semiconductor substrate 101, by in-situ deposition of a doped semiconductor material using, e. g., a chemical vapor deposition (CVD) process, and/or by epitaxial growth of a semiconductor material. The semiconductor substrate 101 further includes an upper semiconductor substrate layer 106 that is formed over the buried semiconductor substrate layer 104. In one example, the upper semiconductor substrate layer 106 has the second conductivity type and a lower dopant concentration than the buried semiconductor substrate layer 104. In other examples, the upper semiconductor substrate layer 106 has the first conductivity type and/or a different dopant concentration. The upper semiconductor substrate layer 106 may be formed by deposition of a doped semiconductor material using, e. g., a chemical vapor deposition (CVD) process, and/or by epitaxial growth of a semiconductor material on top of the buried semiconductor substrate layer 104.

In the example of FIG. 7B, a hard mask 740 including a silicon nitride layer 742, an oxide layer 744 and a polysilicon layer 746 is formed over the upper semiconductor substrate layer 106. In other examples, the hard mask 740 may at least partly include different materials, e. g., borosilicate glass (BSG) or borophosphosilicate glass (BPSG), and/or a different layer sequence.

As illustrated in FIG. 7C, a mask layer 748 is formed over the hard mask 740. The mask layer 748 is structured to expose locations where the first isolation trench 108 and the second isolation trench 110 are to be formed. The structured mask layer 748 includes a first opening having a first width o1 to form the first isolation trench 108. The structured mask layer 748 further includes a second opening having a second width o2 to form the second isolation trench 110. The first width o1 and the second width o2 may be measured at a position at a first main surface 112 of the substrate 101. The first width o1 is larger than the second width o2. The mask layer 748 may include a photoresist, may be referred to as a photoresist layer and may be structured by using photolithography.

FIG. 7D shows the semiconductor device 700 after an etching step has been performed. During the etching step, the mask layer 748 is used to form openings 750 and 752 in the hard mask 740. The openings 750 and 752 extend through the hard mask 740 and a patterned hard mask 740 is provided.

FIG. 7E shows the semiconductor device 700 after the mask layer 748 has been removed and after a further etching step has been performed. During the further etching step, the first isolation trench 108 and the second isolation trench 110 are formed in the substrate 101 by using the hard mask 740 as a mask layer. The first isolation trench 108 is etched to extend from the first main surface 112 of the upper semiconductor substrate layer 106 through the upper semiconductor substrate layer 106 and through the buried semiconductor substrate layer 104 into the lower semiconductor substrate layer 102. Similarly, the second isolation trench 110 is etched to extend from the first main surface 112 of the upper semiconductor substrate layer 106 through the upper semiconductor substrate layer 106 and through the buried semiconductor substrate layer 104 into the lower semiconductor substrate layer 102. The first isolation trench 108 has a first depth d1, the second isolation trench 110 has a second depth d2 and the first depth d1 is larger than the second depth d2. The first depth d1 and the second depth d2 may be measured starting from a position at the first main surface 112 of the substrate 101 to the bottom of the first isolation trench 108 and the second isolation trench 110, respectively. The first isolation trench 108 has a larger depth d1 than the second isolation trench 110 as a result of its width being larger than the width of the second isolation trench 110. In one example (not illustrated), part of the hard mask 740 is removed during the further etching step.

While in the example of FIGS. 7C-7E, the first isolation trench 108 and the second isolation trench 110 are formed concurrently, it should be noted that in other examples, the first isolation trench 108 and the second isolation trench 110 may be formed in consecutive processing steps.

As illustrated in FIG. 7F, a first insulating material 114 is formed that covers an inner sidewall and a bottom of the first isolation trench 108. Further, a second insulating material 118 is formed that covers an inner sidewall and a bottom of the second isolation trench 110. In the example of FIG. 7F, the first insulating material 114 and the second insulating material 118 are formed in a common processing step. In other examples, the first insulating material 114 and the second insulating material 118 may be formed in consecutive processing steps. The first insulating material 114 and the second insulating material 118 are further formed over a surface of the hard mask 740 that faces away from the first main surface 112 of the upper semiconductor substrate layer 106. The first insulating material 114 and the second insulating material 118 include an electrically insulating material. In one example, the first insulating material 114 and/or the second insulating material 118 include a dielectric material. In one example, the first insulating material 114 and/or the second insulating material 118 include at least one of grown and/or deposited oxide or nitride. A chemical vapor deposition (CVD) process may be used for the deposition. In other examples, the first insulating material 114 and/or the second insulating material 118 include other materials or other combinations of electrically insulating materials. The first insulating material 114 and the second insulating material 118 may be a same material or material composition, or the first insulating material 114 and the second insulating material 118 may be different materials or material compositions.

As shown in FIG. 7G, the first insulating material 114 is removed from a bottom of the first isolation trench 108 to form an opening of the first insulating material 114 at the bottom of the first isolation trench 108. Besides, the first insulating material 114 and the second insulating material 118 are removed from the surface of the hard mask 740 that faces away from the first main surface 112 of the upper semiconductor substrate layer 106. The first insulating material 114 and the second insulating material 118 may be removed by using an etching process. The first insulating material 114 and the second insulating material 118 may be removed in a common etching step or in consecutive etching steps.

As illustrated in FIG. 7H, the first isolation trench 108 is filled with a first electrically conductive material 120. In the example of FIG. 7H, the second isolation trench 110 is not filled with any electrically conductive material to provide a semiconductor device 700 that is similar to the semiconductor devices 100A as illustrated and described in connection with FIG. 1A. That means, no portion of the second isolation trench 110 is filled with any electrically conductive material. The width of the second isolation trench 110 is selected in a way that the second isolation trench 110 was completely filled with the second insulating material 118 during one of the previous manufacturing steps. In other examples, only a minor portion (e.g., less than 50%) of the second isolation trench 110 is filled with a second electrically conductive material 222 to provide a semiconductor device 700 that is similar to the semiconductor devices 200, 300 as illustrated and described in connection with FIGS. 2 and 3. During operation of the semiconductor device 700, the second electrically conductive material 222 may be electrically floating.

In one example, the first electrically conductive material 120 and the second electrically conductive material 222 are formed in a common processing step. In other examples, the first electrically conductive material 120 and the second electrically conductive material 222 may be formed in different processing steps. In one example, the first electrically conductive material 120 and/or the second electrically conductive material 222 include at least one of polysilicon or metal. In other examples, the first electrically conductive material 120 and/or the second electrically conductive material 222 include other materials or other combinations of electrically conductive materials. The first electrically conductive material 120 and the second electrically conductive material 222 may be a same material or material composition, or the first electrically conductive material 120 and the second electrically conductive material 222 may be different materials or material compositions.

As illustrated in FIG. 7H, the filling of the first isolation trench 108 comprises filling the first electrically conductive material 120 in the opening of the first insulating material 114 at the bottom of the first isolation trench 108 to provide a connection of the first electrically conductive material 120 to the lower semiconductor substrate layer 102. The lower semiconductor substrate layer 102 may be biased to a predefined voltage level via the first electrically conductive material 120 that extends through the opening of the first insulating material 114 at the bottom of the first isolation trench 108. It is to be noted that in other examples, in contrast to the illustration in FIG. 7G, the first insulating material 114 may not be removed from the bottom of the first isolation trench 108 and the first electrically conductive material 120 may not be connected to the lower semiconductor substrate layer 102 at the bottom of the first isolation trench 108. That means, the first electrically conductive material 120 is separated from the substrate 101 by the first insulating material 114 at both the sidewalls and the bottom. In this other example, the lower semiconductor substrate layer 102 may be configured to be set to an electrical potential in a different way, e. g., by using a sinker.

FIG. 7I shows the semiconductor device 700 after the hard mask 740 has been removed from the first main surface 112 of the upper semiconductor substrate layer 106. The hard mask 740 may be removed by using an etching process and/or a chemical mechanical polish (CMP) process.

The method of manufacturing the semiconductor device 700 as illustrated and described in connection with FIGS. 7A-7I is provided as an example. The manufacturing steps described do not necessarily have to be carried out in the order given. Some of the manufacturing steps may be carried out concurrently. There may be different, additional and/or intermediate manufacturing steps. In one example, well regions and/or doped regions may be formed in the upper semiconductor substrate layer 106 to form parts of functional devices. These well regions and/or doped regions may be formed by diffusion and/or implantation. In one example, isolation regions may be formed to electrically isolate device structures from each other. These isolation regions may be at least partly formed within the upper semiconductor substrate layer 106. These isolation regions may include shallow trench isolation (STI) and/or local oxidation of silicon (LOCOS) structures. In one example, a region that has a locally increased dopant concentration may be formed at the bottom of the first isolation trench 108. This region may be similar to the region 430 as illustrated and described in connection with FIG. 4A. This region having a locally increased dopant concentration may be formed by diffusion and/or implantation.

Examples of the present invention are summarized here. Other examples can also be understood from the entirety of the specification and the claims filed herein.

Example 1: A semiconductor device comprising: a lower semiconductor substrate layer of a first conductivity type; an upper semiconductor substrate layer; a buried semiconductor substrate layer of a second conductivity type interposed between the lower semiconductor substrate layer and the upper semiconductor substrate layer; a first isolation trench formed at a first main surface of the upper semiconductor substrate layer and extending through the upper semiconductor substrate layer and the buried semiconductor substrate layer into the lower semiconductor substrate layer, wherein the first isolation trench comprises a first insulating material formed at an inner sidewall of the first isolation trench, and wherein the first isolation trench is filled with a first electrically conductive material; and a second isolation trench formed at the first main surface of the upper semiconductor substrate layer and extending through the upper semiconductor substrate layer and the buried semiconductor substrate layer into the lower semiconductor substrate layer, wherein the second isolation trench comprises a second insulating material formed at an inner sidewall and a bottom of the second isolation trench, and wherein the second isolation trench is either devoid of a second electrically conductive material or only a minor portion (e.g., less than 50%) of the second isolation trench is filled with the second electrically conductive material.

Example 2: The semiconductor device of example 1, wherein only a minor portion (e.g., less than 50%) of the second isolation trench is filled with the second electrically conductive material, wherein the second electrically conductive material extends from the first main surface of the upper semiconductor substrate layer into a vertical direction through a level that is defined by a lower surface of the upper semiconductor substrate layer, and wherein a bottom portion of the second electrically conductive material does not reach a level that is defined by a lower surface of the buried semiconductor substrate layer.

Example 3: The semiconductor device of example 1, wherein only a minor portion (e.g., less than 50%) of the second isolation trench is filled with the second electrically conductive material, wherein the second electrically conductive material extends from the first main surface of the upper semiconductor substrate layer into a vertical direction and a bottom portion of the second electrically conductive material does not reach a level that is defined by a lower surface of the upper semiconductor substrate layer.

Example 4: The semiconductor device of any of the preceding examples, wherein only a minor portion (e.g., less than 50%) of the second isolation trench is filled with the second electrically conductive material and wherein the second electrically conductive material is configured to be electrically floating.

Example 5: The semiconductor device of any of the preceding examples, wherein the first electrically conductive material is connected to the lower semiconductor substrate layer via an opening of the first insulating material at a bottom of the first isolation trench.

Example 6: The semiconductor device of example 5, wherein the lower semiconductor substrate layer comprises a region having a locally increased dopant concentration at the bottom of the first isolation trench.

Example 7: The semiconductor device of any of the preceding examples, wherein the second isolation trench has a second width and the first isolation trench has a first width larger than the second width.

Example 8: The semiconductor device of example 7, wherein a distance between the first isolation trench and the second isolation trench is less than the first width of the first isolation trench.

Example 9: The semiconductor device of any of the preceding examples, wherein the second isolation trench has a second depth and the first isolation trench has a first depth larger than the second depth.

Example 10: The semiconductor device of any of the preceding examples, wherein at least one of the first isolation trench and the second isolation trench has a tapered sidewall.

Example 11: The semiconductor device of any of the preceding examples, further comprising: a first functional device region located at a side of the first isolation trench that faces away from the second isolation trench; and a second functional device region located at a side of the second isolation trench that faces away from the first isolation trench.

Example 12: The semiconductor device of example 11, wherein the first isolation trench and the second isolation trench are arranged in an isolation region of the semiconductor device and wherein the isolation region is arranged between the first functional device region and the second functional device region.

Example 13: The semiconductor device of any of examples 11 or 12, wherein the first functional device region comprises at least one active or passive semiconductor device and wherein the second functional device region comprises at least one active or passive semiconductor device.

Example 14: The semiconductor device of example 13, wherein an active or passive semiconductor device of the first functional device region is configured to operate at a different voltage level than an active or passive semiconductor device of the second functional device region.

Example 15: The semiconductor device of example 14, wherein the active or passive semiconductor device of the second functional device region is configured to operate at a higher voltage level than the active or passive semiconductor device of the first functional device region.

Example 16: The semiconductor device of any of examples 11 to 15, wherein the second isolation trench at least partly surrounds the second functional device region.

Example 17: The semiconductor device of any of examples 11 to 16, wherein the first functional device region is at least partly surrounded by a single isolation trench.

Example 18: The semiconductor device of any of examples 12 to 17, wherein the buried semiconductor substrate layer in the isolation region is configured to be set to a defined potential.

Example 19: The semiconductor device of any of the preceding examples, wherein the first isolation trench at least partly surrounds the second isolation trench.

Example 20: The semiconductor device of any of the preceding examples, wherein a region between the first isolation trench and the second isolation trench is devoid of functional devices.

Example 21: A method of manufacturing a semiconductor device, comprising: forming a first isolation trench extending from a first main surface of an upper semiconductor substrate layer through the upper semiconductor substrate layer and through a buried semiconductor substrate layer into a lower semiconductor substrate layer, forming a second isolation trench extending from the first main surface of the upper semiconductor substrate layer through the upper semiconductor substrate layer and through the buried semiconductor substrate layer into the lower semiconductor substrate layer, forming a first insulating material which covers an inner sidewall of the first isolation trench, forming a second insulating material which covers an inner sidewall and a bottom of the second isolation trench, filling the first isolation trench with a first electrically conductive material; and filling only a minor portion (e.g., less than 50%) of the second isolation trench with a second electrically conductive material or not filling of the second isolation trench with the second electrically conductive material.

Example 22: The method of example 21, wherein the filling of the first isolation trench comprises filling the first electrically conductive material in an opening of the first insulating material at a bottom of the first isolation trench to provide a connection of the first electrically conductive material to the lower semiconductor substrate layer.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

What is claimed is:

1. A semiconductor device, comprising:
a lower semiconductor substrate layer of a first conductivity type;
an upper semiconductor substrate layer;
a buried semiconductor substrate layer of a second conductivity type interposed between the lower semiconductor substrate layer and the upper semiconductor substrate;
a first isolation trench formed at a first main surface of the upper semiconductor substrate layer and extending through the upper semiconductor substrate layer and the buried semiconductor substrate layer into the lower semiconductor substrate layer, wherein the first isolation trench comprises a first insulating material formed at an inner sidewall of the first isolation trench, and wherein the first isolation trench is filled with a first electrically conductive material; and
a second isolation trench formed at the first main surface of the upper semiconductor substrate layer and extending through the upper semiconductor substrate layer and the buried semiconductor substrate layer into the lower semiconductor substrate layer, wherein the second isolation trench comprises a second insulating material formed at an inner sidewall and a bottom of the second isolation trench, and wherein the second isolation trench is either devoid of a second electrically conductive material or less than 50% of the second isolation trench is filled with the second electrically conductive material.

2. The semiconductor device of claim 1, wherein less than 50% of the second isolation trench is filled with the second electrically conductive material, wherein the second electrically conductive material extends from the first main surface of the upper semiconductor substrate layer into a vertical direction through a level that is defined by a lower surface of the upper semiconductor substrate layer, and wherein a bottom portion of the second electrically conductive material does not reach a level that is defined by a lower surface of the buried semiconductor substrate layer.

3. The semiconductor device of claim 1, wherein less than 50% of the second isolation trench is filled with the second electrically conductive material, wherein the second electrically conductive material extends from the first main surface of the upper semiconductor substrate layer into a vertical direction, and wherein a bottom portion of the second electrically conductive material does not reach a level that is defined by a lower surface of the upper semiconductor substrate layer.

4. The semiconductor device of claim 1, wherein less than 50% of the second isolation trench is filled with the second electrically conductive material, and wherein the second electrically conductive material is configured to be electrically floating.

5. The semiconductor device of claim 1, wherein the first electrically conductive material is connected to the lower semiconductor substrate layer via an opening of the first insulating material at a bottom of the first isolation trench.

6. The semiconductor device of claim 5, wherein the lower semiconductor substrate layer comprises a region having a locally increased dopant concentration at the bottom of the first isolation trench.

7. The semiconductor device of claim 1, wherein the second isolation trench has a second width and the first isolation trench has a first width larger than the second width.

8. The semiconductor device of claim 7, wherein a distance between the first isolation trench and the second isolation trench is less than the first width of the first isolation trench.

9. The semiconductor device of claim 1, wherein the second isolation trench has a second depth and the first isolation trench has a first depth larger than the second depth.

10. The semiconductor device of claim 1, wherein at least one of the first isolation trench and the second isolation trench has a tapered sidewall.

11. The semiconductor device of claim 1, further comprising:
a first functional device region located at a side of the first isolation trench that faces away from the second isolation trench; and
a second functional device region located at a side of the second isolation trench that faces away from the first isolation trench.

12. The semiconductor device of claim 11, wherein the first isolation trench and the second isolation trench are arranged in an isolation region of the semiconductor device, and wherein the isolation region is arranged between the first functional device region and the second functional device region.

13. The semiconductor device of claim 11, wherein the first functional device region comprises at least one active or passive semiconductor device, and wherein the second functional device region comprises at least one active or passive semiconductor device.

14. The semiconductor device of claim 13, wherein an active or passive semiconductor device of the first functional device region is configured to operate at a different voltage level than an active or passive semiconductor device of the second functional device region.

15. The semiconductor device of claim 14, wherein the active or passive semiconductor device of the second functional device region is configured to operate at a higher voltage level than the active or passive semiconductor device of the first functional device region.

16. The semiconductor device of claim 11, wherein the second isolation trench at least partly surrounds the second functional device region.

17. The semiconductor device of claim 11, wherein the first functional device region is at least partly surrounded by a single isolation trench.

18. The semiconductor device of claim 12, wherein the buried semiconductor substrate layer in the isolation region is configured to be set to a defined potential.

19. The semiconductor device of claim 1, wherein the first isolation trench at least partly surrounds the second isolation trench.

20. The semiconductor device of claim 1, wherein a region between the first isolation trench and the second isolation trench is devoid of functional devices.

21. A method of manufacturing a semiconductor device, comprising:
forming a first isolation trench extending from a first main surface of an upper semiconductor substrate layer through the upper semiconductor substrate layer and through a buried semiconductor substrate layer into a lower semiconductor substrate layer;
forming a second isolation trench extending from the first main surface of the upper semiconductor substrate layer through the upper semiconductor substrate layer and through the buried semiconductor substrate layer into the lower semiconductor substrate layer;
forming a first insulating material which covers an inner sidewall of the first isolation trench;
forming a second insulating material which covers an inner sidewall and a bottom of the second isolation trench;
filling the first isolation trench with a first electrically conductive material; and
filling less than 50% of the second isolation trench with a second electrically conductive material or not filling the second isolation trench with the second electrically conductive material.

22. The method of claim 21, wherein the filling of the first isolation trench comprises filling the first electrically conductive material in an opening of the first insulating material at a bottom of the first isolation trench to provide a connection of the first electrically conductive material to the lower semiconductor substrate layer.
